(19) United States
(12) Patent Application Publication
(10) Pub. No.: US 2012/0091550 A1
(43) Pub. Date: Apr. 19, 2012

(54) SPECTROSCOPY AND SPECTRAL IMAGING METHODS AND APPARATUS

(75) Inventors: Ricky James Morgan, Chestnut Hill, MA (US); Ali Abtahi, Canyon Country, CA (US); Francisco Tejada, Baltimore, MD (US); Usha Raghuram, Saratoga, CA (US)

(73) Assignee: Aerospace Missions Corporation, El Paso, TX (US)

(21) Appl. No.: 13/155,697

(22) Filed: Jun. 8, 2011

Related U.S. Application Data
(60) Provisional application No. 61/353,019, filed on Jun. 9, 2010.
(60) Provisional application No. 61/385,595, filed on Sep. 23, 2010.
(60) Provisional application No. 61/390,782, filed on Oct. 7, 2010.
(60) Provisional application No. 61/493,066, filed on Jun. 3, 2011.

(51) Int. Cl. H01L 31/0232; H01L 31/18

(52) U.S. Cl. 257/432; 438/65; 257/E31.127

(57) ABSTRACT

The invention pertains to a new type of standing wave filter in which the detector is located within the cavity, rather than outside the cavity and methods of manufacturing such a filter.

### RELATED APPLICATION

This application is a non-provisional of U.S. provisional patent application No. 61/353,019 filed Jun. 9, 2010, U.S. provisional patent application No. 61/381,595 filed Sep. 10, 2010, U.S. provisional patent application No. 61/390,782 filed Oct. 7, 2010, and U.S. provisional patent application No. 61/493,066 filed Jun. 3, 2011, all of which are incorporated herein fully by reference.

### FIELD OF THE INVENTION

The invention pertains to the fields of spectroscopy and spectral imaging.

### BACKGROUND

Spectroscopy is the science of determining information about the spectral content of an electromagnetic radiation source. Thus, in its broadest sense, the science of spectroscopy encompasses basic photography cameras since a photograph contains spectral information about the observed scene, namely, the colors of light emanating from the observed scene. Hereinafter, we will sometimes use the term “light” as shorthand to refer to electromagnetic radiation of any wavelength. However, this is not intended to limit the discussion to electromagnetic radiation that is in the visible spectrum.

A spectroscope observes light from a source and determines spectral information about that light. The light source may be virtually anything, including, an object that produces its own light (such as a star, a laser, or the molecules involved in a phosphorescent chemical reaction), light that is reflected off of an object, and light that passes through an object. Spectral information about an original source of light can provide information about the chemical composition of the source of the light. Likewise, if one knows the spectral composition of the original light source, light reflected from or light transmitted through an object can provide information about the chemical composition of the object. For instance, the portion of the light spectrum that can and cannot pass through an object could disclose the chemical composition of the object. The same is true for light reflected from an object.

Spectroscopes with extremely high spectral resolution are useful in many applications including scientific and military applications. For instance, spy planes may carry cameras capable of capturing images containing very broad spectral information and very high spectral resolution in order to detect the existence of certain materials, to see through things that are opaque to the visible eye, and/or to provide highly detailed spectroscopic images.

One form of spectroscopy, known as standing wave spectroscopy, takes advantage of the constructive interference that occurs when a beam of light of a particular wavelength is reflected back on itself so that two beams of the same light interfere with each other. FIG. 1A is a diagram illustrating the basic structure of a standing wave spectroscope 100. It should be understood that, while FIG. 1A (as well as other figures in this specification, such as FIGS. 2A, 2B, and 3) shows the light beam 101 as a line and shows each segment 101-1, 101-2 displaced vertically from the preceding segment, in actuality, the beam and each segment thereof has an actual width and that the beam segments are not vertically displaced from each other as illustrated, but rather at least partially physically overlap. They are shown as lines and vertically offset from each other so that they do not overlap in the drawings in order to allow the various beam segments being discussed to be visually differentiated from each other for purposes of illustration and discussion.

In FIG. 1A, a continuous light beam 101 propagating in a first direction reflects off reflective surface 106, with no phase change on reflection, so that it interferes with itself in the space 102. A detector 108 detects the interfering light in space 102 without significantly disturbing the beam. Light having a wavelength equal to twice the distance, d, between the reflector 106 and the detector 108 (and harmonics thereof) will interfere constructively and produce a relatively high amplitude signal that is detected by the detector 108. Light at other frequencies will interfere destructively and have lower amplitude, with the amplitude decreasing as the distance d becomes increasingly different from ½ the wavelength of the light. FIG. 1B illustrates intensity of the detected light at detector 108 for a monochromatic light beam as a function of the distance, d, between the reflector 106 and the detector 108, assuming the reflectivity of the detector is relatively high. As can be seen in FIG. 1B, the detected intensity is greatest at ½ the wavelength, θ, of the light, tapers off on either side of θ/2, and is periodic, such that there are multiple peaks at different distances, d. One property indicative of the sensitivity of a spectroscope to wavelength is known as the full wave half maximum (FWHM) value. The FWHM is the wavelength range surrounding wavelength θ for which the signal amplitude is equal to or greater than half the maximum signal amplitude M.

Thus, by measuring the intensity of the light detected at the detector and scanning the distance, d, between the reflector 106 and the detector 108, one can determine the spectral content of a light beam.

FIG. 2A illustrates another spectroscopy technique utilizing what is known as a Fabry-Perot cell 200. In a Fabry-Perot cell, a light beam 201 enters a space or cavity 203 between two reflectors 204, 205 with a detector 208 positioned outside of the cavity behind one or both of the reflectors. As in a standing wave spectrometer such as described above, the various reflected segments 201-1 through 201-6 of continuous light beam 201 will interfere with themselves in the cavity, thus producing total constructive interference in the rightward direction and total destructive interference in the leftward direction with respect to any light having a wavelength equal to 2l. As is well known, when the distance, l, between the two reflectors is very small, on the order of about one wavelength or less of the light in the cavity, the reflectivities or transmissivities of the reflectors 204, 205 do not behave individually according to classical geometric optics, but rather will depend upon the distance, l, between the two reflectors. For instance, when l is ½ the wavelength of the beam in the cavity, such that the beam segments 201-1, 201-3, and 201-5 that are propagating in the rightward direction in cavity 203 are in phase with each other and interfere entirely constructively, then cell 200 will behave completely transparently to beam 201. On the other hand, when light beam segments 201-2, 201-4, and 201-6 interfere constructively for l equal to one quarter the wavelength of the light beam 201, the exact opposite would be true, i.e., all the light would be reflected in cell 200.

Thus, a detector 208 placed behind one of the reflectors 204 or 205 would detect light of an intensity that would vary as a function of the ratio of l to the wavelength content of the light in the cavity 203. Thus, by varying l, a Fabry-Perot cell can be used to determine the wavelength content of a light beam. Light at other wavelengths essentially will interfere partially destructively or constructively. Again, by varying the distance between the two reflectors, the cell can be used to determine the wavelength content of light in the cavity. A detector could be placed behind each reflector to increase the sensitivity of measurement. However, in theory, both detectors should detect essentially complementary signals, thus revealing identical information.

FIG. 2B is a diagram of a modified Fabry-Perot cell 210 in which the cavity 213 between the two mirrors 214, 215 is not a vacuum or air-filled, but is instead filled with a light absorbing material 216, which, for instance, may be a gas or a solid. The light absorbing material 216 can be more absorbent of certain wavelengths and less absorbent of others. In this manner, one can create a cavity that is extremely sensitive to a particular wavelength of light, i.e., it has a very narrow full width half maximum (FWHM) value.

In theory, all light in a perfect Fabry-Perot cell will be transmitted through one of reflectors 204 and 205 (i.e., the amount of light entering the cell is equal to the amount of light exiting the cell per unit time), with the percentage of the light that is transmitted through each reflector 204, 205 depending on the distance between the two reflectors. For example, if l is ½ the wavelength of monochromatic light in the cell, then 100% of the light in the cell will be transmitted through reflector 204. If l is ¼ the wavelength of monochromatic light in the cell, then 100% of the light in the cell will be transmitted through reflector 205. At other distances, some percentage of the light may be transmitted through reflector 204 and the rest is transmitted through reflector 205.

However, no Fabry-Perot cell is perfect. In actuality, some light always is reflected and some always is transmitted. The Q of a Fabry-Perot cell is a measure of the quality of the cell. More specifically, the Q of a cell is the number of times that a light beam will bounce back and forth in the cell before the amount of light entering the cell is equal to the amount of light exiting the cell per unit time. The higher the Q in a Fabry-Perot cell, the narrower the FWHM. This, in turn, means that the cell is more sensitive to wavelength and produces a more robust output measurement.

One common problem with the manufacture of Fabry-Perot cells is the placement of the circuitry needed to move one of the reflectors (in order to vary l over time) and the circuitry of the detector. Generally, one the reflectors must have circuitry directly behind it in order to make the reflector translatable so as to vary the gap of the cavity. The detector therefore must be placed behind the other reflector because the light passing through the movable reflector cannot make it through the movement circuitry to be detected by a detector positioned behind that reflector. With the detector circuitry on one side of the cavity and the movement circuitry behind the other side of the cavity, it is difficult to provide an open pathway for light to initially enter the cavity.

### SUMMARY OF INVENTION

The invention pertains to a new type of standing wave filter in which the detector is located within the cavity, rather than outside the cavity and methods of manufacturing such a filter.

### BRIEF DESCRIPTION OF THE DRAWINGS

FIG. 1A is a diagram illustrating a standing wave spectroscope of the prior art.

FIG. 1B is a graph illustrating a spectral distribution measurement in a standing wave spectroscopic cell.

FIG. 2A is a diagram illustrating a Fabry-Perot cell of the prior art.

FIG. 2B is a diagram illustrating another type of Fabry-Perot cell of the prior art.

FIG. 3 is a diagram illustrating a standing wave filter in accordance with a particular embodiment of the invention.

FIGS. 4A-4F are diagrams illustrating various stages in one semiconductor fabrication technique for manufacturing a spectroscope in accordance with the principles of the invention.

FIG. 4G is a diagram illustrating operation of a spectroscope in accordance with the principles of the invention.

FIG. 5 is a diagram illustrating one particular embodiment of an array of spectroscopes in accordance with the principles of the invention in which each pixel of the array is individually adjustable in cavity depth.

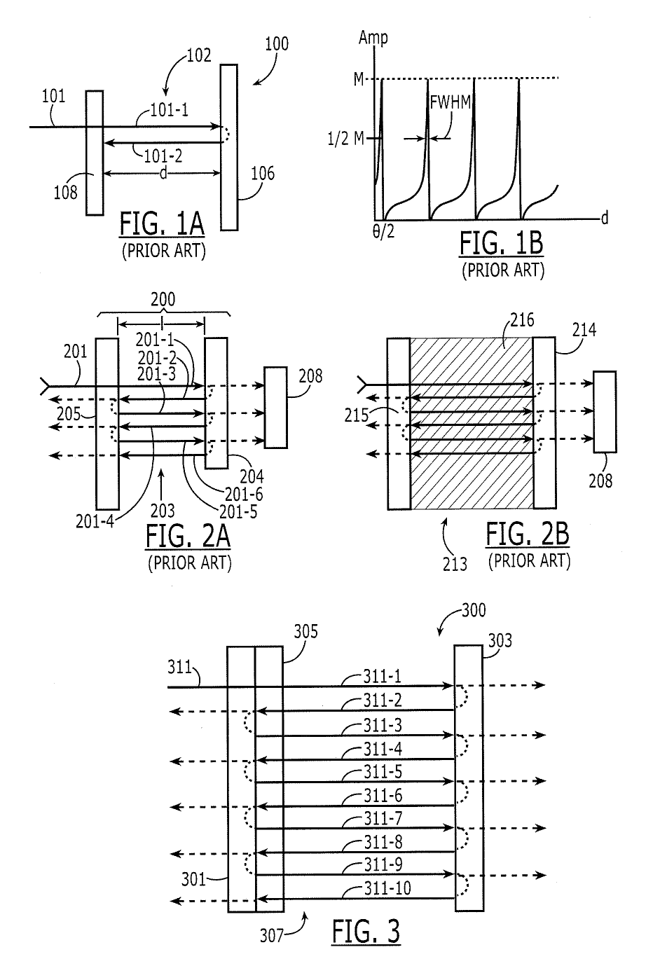

### DETAILED DESCRIPTION OF THE EMBODIMENTS

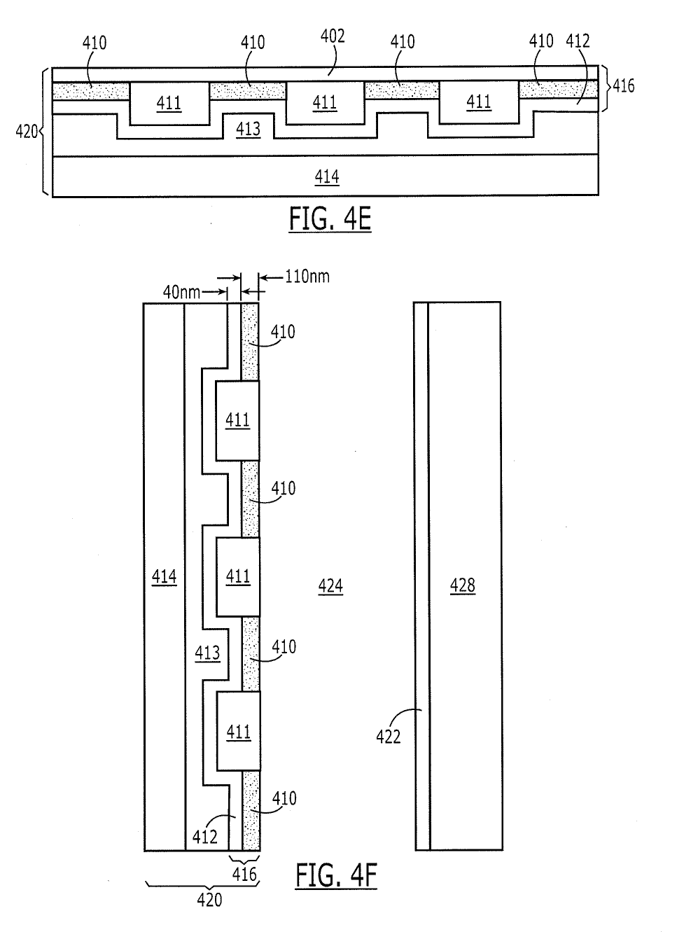

FIG. 3 illustrates the basic construction of a spectroscope 300 in accordance with one embodiment of the invention. As in a conventional Fabry-Perot cell, the basic components of the cell are a first reflector 301, a second reflector 303, and a light detector 305. In FIG. 3, the detector 305 is inside the cavity 307 or space between the two reflectors 301, 303 rather than outside the reflectors, as with a conventional Fabry-Perot cell. In this embodiment, the detector 305 is attached to the first reflector 301.

A light beam 311 is directed into the cavity 307 through the first reflector 301 and the detector 305. The light beam 311 bounces back and forth in the cavity 307 between the first and second reflectors 301, 303. The detector 305 is semi-transparent so that light can pass through the detector in both directions to enable light to reflect back and forth between the two reflectors while simultaneously being at least partially detected by the detector 305. Since the detector 305 is mounted on the face of the first reflector 301, the light beam 311 reflected from the second reflector 303 will also impinge on the detector 305. For each round-trip pass through the cavity, the light beam 311 passes through the detector 305 twice. The detector 305 may be positioned anywhere within the cavity. However, as will be described in more detail below, one fabrication process lends itself to locating the detector directly on one of the reflectors, as shown.

As with a Fabry-Perot cell, the inventive cell can be tuned to detect any wavelength content of the light within the cavity by varying the optical cavity depth (e.g., by varying the gap distance between the reflectors or by varying the index of refraction within the gap) between the two reflectors. The spectrum of the light is measured by recording the strength of the detected signal as a function of the cavity depth.

Because the detector 305 is inside the cavity 307, it must be very thin (on the order of less than a wavelength of the light). As is well known, generally, the thinner the detector, the less light impingent on it is absorbed, i.e., detected (at least at thicknesses less than a wavelength of the impingent light). Generally, in a conventional Fabry-Perot cell, in which the detector is outside of the cavity, the detector can be made much thicker than the wavelength of the light being detected so that the detector will absorb substantially all of the impingent light. Contrarily, a detector such as detector 305 placed inside the cavity 307 generally should be significantly thinner than a wavelength of the light in the cavity. Hence, it is likely to be unable to absorb all of the light of each beam segment that impinges on it. However, the absorption efficiency of the detector is not a concern because it is inside the cavity, and therefore, receives light from all of the beam segments impingent on the reflector 301 on which it is mounted. Hence, all light in the cavity eventually will be absorbed by the detector 305, in any event.

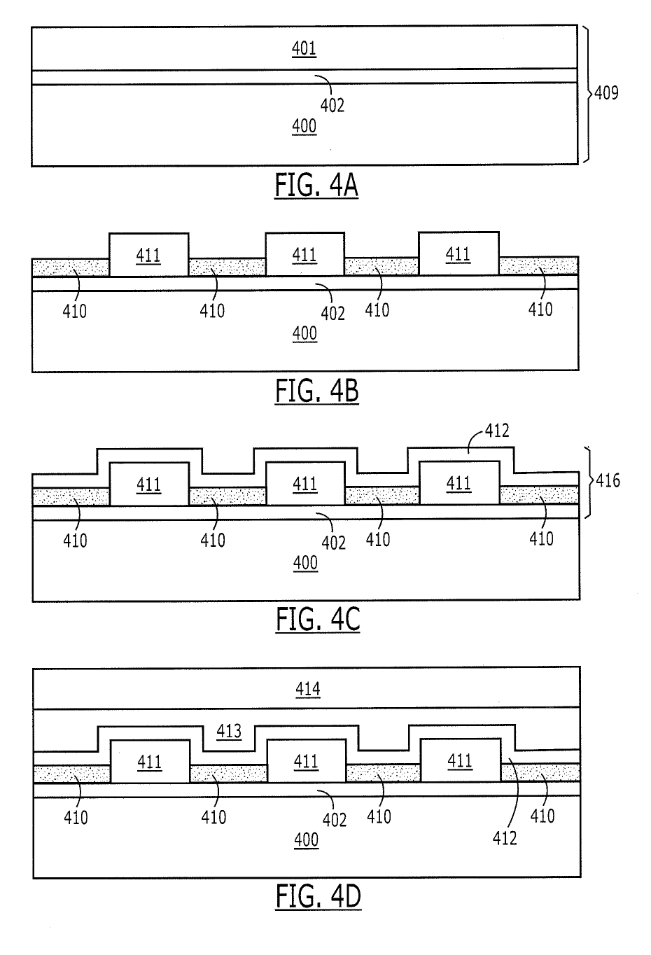

More particularly, if we call the sensitivity of the detector 305 to the light 311, α, then the magnitude of the signal generated by the detector is a function of α and the amount of light hitting the detector. Thus, the spectroscope of FIG. 3 outputs a measurement signal that is proportional to Qxα, where Q is the number of times the light passes through the detector, e.g., 10 times in FIG. 3, as compared to a measurement signal proportional to just α for the conventional Fabry-Perot spectroscope of FIG. 2. In essence, the filter/detector of the present invention theoretically should be approximately Q times more sensitive than a conventional Fabry-Perot cell using an external detector of the same absorption efficiency.

As will be described in more detail below, another advantage of the invention is that spectroscopes in accordance with the above-described principles can be readily manufactured using inexpensive and practical semiconductor manufacturing techniques. Moreover, a focal plane array of such spectroscopes can be manufactured using inexpensive and practical semiconductor manufacturing techniques. Even further, a focal plane array of such spectroscopes can be manufactured in which each spectroscope is independently wavelength tunable (e.g., the gaps between the reflectors of the cells can be varied individually for each cell). Accordingly, different cells in the array can be used independently and simultaneously to detect different wavelengths of light from different spots, and/or it is possible to form arrays comprised of multiple super-pixels, wherein each super-pixel comprises two or more cells focused on the same spot (or very close spots), but which are tuned to detect different wavelengths. This technique may be used to provide much faster image spectral data.

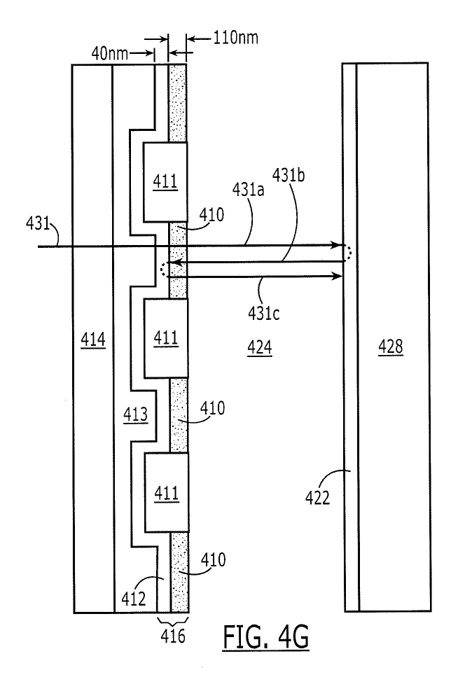

FIGS. 4A through 4F illustrate various stages of one fabrication technique for producing a spectroscope in accordance with the principles of the present invention with virtually no limitation as to minimum gap size except for the depth of the detector within the gap, which can be as small as 10 nanometers or smaller. This technique utilizes semiconductor fabrication techniques, including the use of silicon on insulator (SOI) technology.

With reference to FIG. 4A, the starting point in this exemplary fabrication embodiment is a silicon on insulator (SOI) substrate 409 comprised of a thin silicon layer 401, an insulating layer 402 (e.g., a thin oxide layer), and a thick silicon layer 400. The SOI substrate 409 may be fabricated, for instance, using the Smartcut™ process developed by SOITEC of France.

Turning now to FIG. 4B, the detectors 410, measurement-related circuitry 411, and any other semiconductor devices can be fabricated in the silicon layer 401 in accordance with conventional semiconductor fabrication processes.

Turning to FIG. 4C, next, a reflector 412 is then placed on top of the oxide/detector/circuitry 402, 410, 411. This can be done using any reasonable semiconductor fabrication technique, such as chemical vapor deposition. The reflector 412 only needs to be placed on top of the detectors 410, but can be placed over other parts as well.

Turning to FIG. 4D, next, a transparent substrate 414, such as quartz, glass, or sapphire, is attached to the reflector 412, such as by using a transparent bonding adhesive 413. As will become clear from the following discussion, light can be introduced into the cell cavity through the transparent substrate 414, transparent bonding adhesive, and the reflector 412. At this point, the structure comprises a reflector 412, detector 410, and measurement-related circuitry 411 on an insulator 402 sandwiched between a substrate 414 and a silicon substrate 400. Since the substrate 414 can provide the necessary structure for supporting the reflector/detector 410/412, the silicon substrate 400 now may be removed. Thus, referring now to FIG. 4E, the assembly has been flipped over so that the substrate 414 is now on the bottom Furthermore, the silicon substrate 400 has been removed by, for instance, conventional semiconductor etching with the thin oxide layer 402 serving as an etch stop for the silicon etching process. Thus, as shown in FIG. 4E, what remains is an assembly 420 comprised of the reflector/detector unit (hereinafter reflector/detector 416) on a transparent substrate comprised of silicon substrate 414 and adhesive 413.

Turning now to FIG. 4F, a second reflector 422 is positioned next to the assembly 420. The second reflector 422 preferably is mounted on a system such as a microelectromechanical system (MEMS) 428 that can vary the cavity 424 depth between the two reflectors 412, 422 for purposes of tuning the cavity 424 to different wavelengths. The only thing in the cavity 424 between the first reflector 412 and the second reflector 422 is the detector 410 or the circuitry 411.

A prototype structure substantially as described herein was fabricated in which the entire assembly reflector/detector 416 was approximately 220 nanometers thick. More particularly, the reflector 412 was approximately 15-20 nanometers thick and the detector was approximately 120 nanometers thick. Accordingly, the cavity 424 in the prototype could be as small as 120 nanometers in depth. The thicknesses disclosed are actual minimum values measured. Thicknesses can be smaller, but were limited in the prototype structure by the resolution of the particular fabrication equipment used and by the selection of readily available, and inexpensive, materials for use.

FIG. 4G illustrates operation of spectroscope of FIG. 4F. Specifically, light 431 enters the cavity 424 by passing through the substrate 414 and the reflector/detector unit 416. The light 431 bounces back and forth between the two reflectors 412, 422 as illustrated by light beam segments 431a-431c. For each roundtrip pass between the two reflectors 412, 422, at least a portion of the light enters the detector 410 and is detected.

The above-described fabrication technique lends itself well to the fabrication of a focal plane array for spectroscopic imaging comprising millions of spectroscopic cells in which each cell is independently and simultaneously wavelength tunable. Accordingly, this technology may be used to build, at low cost and high production yield, high spatial resolution imaging devices (e.g., cameras) that have relatively high spectral resolution and individually tunable cells. In one exemplary embodiment of a focal plane array, the second reflector and the mechanics for moving the second reflector may be a MEMS Mirror Array. In one embodiment, we used a Fraunhofer Phase Former Kit available from Fraunhofer IPMS of Dresden, Germany. It is a piston-type MicroMirror Array (MMA) consisting of a segmented array of 240×200 mirror elements with a 40 micron pixel size. Each pixel can be electrostatically addressed and deflected independently by means of underlying integrated CMOS address circuitry at an 8 bit height resolution. MMA programming is performed in an interlaced line-by-line fashion.

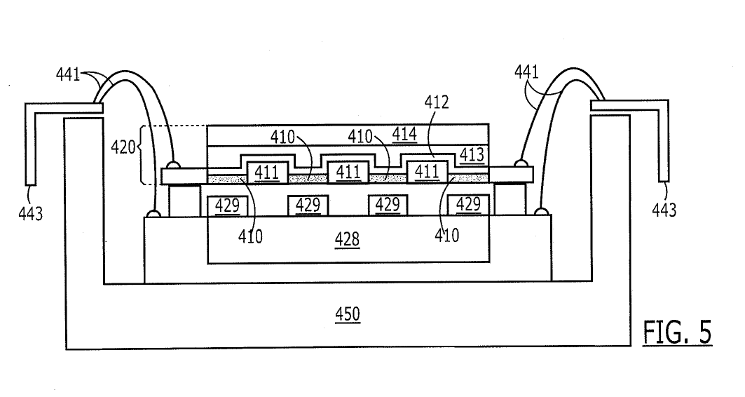

FIG. 5 is a diagram illustrating the construction of one such practical focal plane array in accordance with one exemplary embodiment of the invention. Particularly, the structure 420 comprising the substrate 414 and reflector/detector 416 is mounted upside down on a MEMS mirror array 428 including individually mechanically movable mirrors 429, such as the aforementioned Fraunhofer Phase Former Kit. The MEMS circuitry and detector circuitry connections are made through wire bonds 441 to a frame 443. The entire assembly is encapsulated in a polymer encapsulation 450. The top of the substrate 414 protrudes through the polymer encapsulation 450 since light must enter into the cavity 424 through the transparent substrate 414. Conventional semiconductor encapsulation techniques can be employed except that the encapsulation would end at the sidewalls of the substrate 414. Semiconductor encapsulation techniques are available in which a hermetic seal can be formed between the encapsulation polymer and the sidewall of the transparent substrate.

Having thus described a few particular embodiments of the invention, various alterations, modifications, and improvements will readily occur to those skilled in the art. Such alterations, modifications, and improvements as are made obvious by this disclosure are intended to be part of this description though not expressly stated herein, and are intended to be within the spirit and scope of the invention. Accordingly, the foregoing description is by way of example only, and not limiting. The invention is limited only as defined in the following claims and equivalents thereto.

1. An apparatus for determining the spectral content of a beam of electromagnetic radiation comprising:
a first reflector;
a second reflector;
a space defined between the first reflector and the second reflector in which the beam may reflect back and forth between the two reflectors; and
an electromagnetic radiation detector located in the space between the first reflector and second reflector.

2. The apparatus of claim 1 wherein the detector is disposed on the first reflector.

3. The apparatus of claim 2 wherein the detector is semi-transparent, whereby the beam may partially pass through the detector.

4. The apparatus of claim 1 further comprising:
a substantially transparent support structure, and wherein the first reflector comprises first and second opposed major surfaces and the detector is disposed within the space on the first major surface and the transparent support structure is disposed without the space on the second major surface.

5. The apparatus of claim 4 wherein the substantially transparent support structure is a quartz substrate.

6. The apparatus of claim 1 wherein an optical path length of the space between the first reflector and the second reflector is variable.

7. The apparatus of claim 6 further comprising:
a material disposed in the space having an index of refraction that can be varied in order to vary the optical path length of the space between the first reflector and the second reflector.

8. The apparatus of claim 1 wherein the detector is a semiconductor on insulator integrated circuit.

9. The apparatus of claim 1 wherein the second reflector is movable relative to the first reflector so as to vary the distance that a light beam travels between the first reflector and the second reflector.

10. An array of spectroscopes comprising:
a first reflector;
a plurality of electromagnetic radiation detectors disposed on the first reflector;
a plurality of second reflectors arranged in opposing relation to the first reflector so that electromagnetic radiation may be caused to bounce back and forth in a space between the first reflector and each reflector of the plurality of second reflectors, wherein the plurality of electromagnetic radiation detectors are within the space and detect at least a portion of the electromagnetic radiation in the space.

11. The array of claim 10 wherein the plurality of second reflectors comprises a microelectromechanical device in which each reflector of the second plurality of reflectors is separately movable relative to the first reflector.

12. The array of claim 10 wherein each reflector of the second plurality of reflectors is separately movable relative to the first reflector so as to vary the distance that a beam of electromagnetic radiation traverses in a roundtrip pass between the first reflector and the corresponding one of the second reflectors.

13. The array of claim 10 further comprising a transparent substrate, the transparent substrate and the plurality of electromagnetic radiation detectors disposed on opposing sides of the first reflector.

14. A method of fabricating a spectroscope comprising:
fabricating an electromagnetic radiation detector on an insulator layer of a semiconductor on insulator substrate, the semiconductor on insulator substrate comprising an insulator layer and a semiconductor layer;
positioning a first reflector on the electromagnetic radiation detector on the semiconductor on insulator substrate;
positioning a transparent substrate on the first reflector opposite the electromagnetic radiation detector;
removing the semiconductor layer of the semiconductor on insulator substrate; and
placing a second reflector adjacent the first reflector so as to provide a space in which a beam of electromagnetic radiation can bounce back and forth between the first reflector and the second reflector with the detector in the space between the first reflector and the second reflector.

15. The method of claim 14 wherein the second reflector is movable relative to the first reflector.

16. The method of claim 14 wherein the second reflector comprises a plurality of second reflectors, each one of the second reflectors being separately movable relative to the first reflector.

17. The method of claim 14 wherein the second reflector comprises a microelectromechanical mirror array.

18. The method of claim 14 wherein the transparent substrate is a quartz substrate.

19. The method of claim 14 wherein the removing of the semiconductor layer of the semiconductor on insulator substrate comprises etching using the insulator layer as an etch step.

20. The method of claim 14 wherein the attaching the first reflector comprises attaching the first reflector to the detector.

21. The method of claim 14 wherein the placing the second reflector comprises placing a microelectromechanical mirror array comprising a plurality of independently movable mirrors adjacent the first reflector.

22. The method of claim 14 wherein the semiconductor on insulator substrate comprises a first semiconductor layer, an insulator layer, and a second semiconductor layer.
